(19) United States
(12) Patent Application Publication
(10) Pub. No.: US 2004/0019842 A1
(43) Pub. Date: Jan. 29, 2004

(54) Efficient decoding of product codes

(76) Inventors: Cenk Argon, Atlanta, GA (US); Steven W. McLaughlin, Decatur, GA (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/202,252

(22) Filed: Jul. 24, 2002

(51) Int. Cl. H03M 13/00

(52) U.S. Cl. 714/755

(57) ABSTRACT

A system is provided for decoding product codes. The system includes a processor configured with logic to generate syndromes for a first codeword test pattern and generate syndromes for subsequent codeword test patterns using a recursive function of the syndromes generated for a codeword test pattern previously generated.

### TECHNICAL FIELD

The present invention is generally related to error correction coding, and, more particularly, is related to a system and method for decoding product codes.

### BACKGROUND OF THE INVENTION

Communication systems generally employ error correction coding to reduce the need for re-transmitting data. For example, when some systems, such as the Internet, detect errors at the receiver end, they re-transmit. One problem with this scheme is that retransmission also produces increased latency in a communication system. Many varieties of error correction schemes exist. For example, data can be sent with added bits, or overhead, that include a repetition code, such as 3 bits of value zero (e.g., 0 0 0). At the receiving end, if two of the three bits are zero and one bit was corrupted (e.g. “flipped”) in the transmission, one error correcting code mechanism employed could be that the majority rules, and the correction will be to change the bit from a “1” value to a “0” value. One problem with repetition coding is that of added overhead, which can result in increased decoding latency.

Thus, one goal in error correction coding is to reduce the need for retransmissions, yet provide error free communication. In providing such communications, decoders have been developed to process successive iterations of error correction algorithms to find errors and correct them for sometimes vast amounts of data, such as those found in video, audio, and/or data transmissions. With improvements in digital signal processing, decoders are being pressed to handle even greater amounts of data, unfortunately often with increased processing latency.

Turbo product codes (TPCs) are a subcategory of product codes that can achieve performances near the Shannon limit and are an attractive option when compared to the decoding complexity of parallel concatenated convolutional turbo codes. Chase algorithms have been adapted to work on TPCs, and address some of the shortcomings of other error correction schemes, especially TPCs with one-error-correcting extended BCH codes, which have low-complexity. For further information on Chase algorithms, refer to “A class of algorithms for decoding block codes with channel measurement information,” by D. Chase, IEEE Trans. On Information Theory, vol. IT-18, no. 1, pp. 170-182, January 1972, herein incorporated by reference. For an additive white Gaussian noise (AWGN) channel, it is well known that the squared Euclidean distance metric is used in the calculation of the reliability, or log-likelihood ratio (LLR), of the transferred information. The LLR can be described by the following Euclidean distance metric equations:

Λ(dⱼ)=log[(Pr(cⱼ=1|R)/(Pr(cⱼ=0|R)] (Eq. A)

Λ(dⱼ)≈[(|R−\hat{D}|−|R−D|²)/4](2dⱼ−1) (Eq. B)

If R=r₀ . . . rₙ₋₁ denotes the received noisy sequence, C=c₀ . . . cₙ₋₁ is the transmitted codeword, D=d₀ . . . dₙ₋₁ is the decided codeword after Chase decoding and \hat{D}=\hat{d}₀ . . . \hat{d}ₙ₋₁ (if it exists) is the most likely competing codeword among the candidate codewords with \hat{d}ⱼ≠dⱼ, then for a stationary AWGN channel and a communication system using binary phase shift keying (BPSK), the reliability, or LLR of bit position j can be approximated by equations A and B, where dⱼε{0,1}, j=0,1, . . . , n−1, and |R−X|² denotes the squared Euclidean distance between vectors R and X.

After calculating the LLR, the extrinsic information wⱼ is typically obtained using,

wⱼ=Λ(dⱼ)−rⱼ, if a competing \hat{D} exists, (Eq. C)

wⱼ=β(2dⱼ−1), if no competing \hat{D} exists, (Eq. D)

where β is a reliability factor which is applied to approximate the extrinsic information if there is no competing codeword. This reliability factor increases with each iteration and satisfies 0≦β≦1. Once the extrinsic information has been determined for all bit positions, the input to the next decoding stage is updated as,

r′ⱼ=rⱼ+γwⱼ, (Eq. E)

where γ is a weight factor introduced to combat high bit-error-rate (BER) and high standard deviation in wⱼ during the first iterations. As in the case for the reliability factor β, the weight factor γ also increases with each iteration and satisfies 0≦γ≦1. As is evident from the complexity of the equations above, even with TPCs, there are still many operations required due to the repeated application of the Chase algorithm on the rows or columns at each stage.

Further, the weight and reliability factors γ and β used in scaling and approximating of extrinsic information in decoding of TPCs are typically modified during decoding operations. One mechanism employed in the prior art is to increase these parameters with each iteration, e.g., γ(i)=[0.0, 0.2, 0.3, 0.5, 0.7, 0.9, 1.0, 1.0] and β(i)=[0.2, 0.4, 0.6, 0.8, 1.0, 1.0, 1.0, 1.0], where i denotes the number of half-iterations. The increase in these factors is based on the assumption that the extrinsic information becomes more reliable with each iteration. In order to make these factors independent from the product code used, other mechanisms include normalizing the mean absolute value of the extrinsic information to one (1) before passing it to the next decoding stage, i.e., the extrinsic information wⱼ is multiplied by 1/ρ where ρ is the mean of |wⱼ|. While this is a reasonable approach, it brings additional complexity and decoding latency in the implementation of the TPC decoder.

Thus, a heretofore unaddressed need exists in the industry to address the aforementioned and/or other deficiencies and inadequacies.

### SUMMARY OF THE INVENTION

The present invention provides, among others, a system for decoding product codes. One embodiment of such a system includes a processor configured with logic to generate syndromes for a first codeword test pattern and generate syndromes for subsequent codeword test patterns using a recursive function of the syndromes generated for a codeword test pattern previously generated.

The present invention can also be viewed as providing methods for decoding product codes. In this regard, one embodiment of such a method, among others, can be broadly summarized by the following steps: generating syndromes for a first codeword test pattern; and generating syndromes for subsequent codeword test patterns using a recursive function of the syndromes generated for a codeword test pattern previously generated.

Other systems, methods, features, and advantages of the present invention will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1A is a block diagram of one example communication system that includes an example efficient decoding system (EDS) that employs efficient decoding methods, in accordance with one embodiment of the invention.

FIG. 1B is a schematic diagram of select internal circuitry of one embodiment of the example EDS depicted in FIG. 1A.

FIG. 1C is a schematic diagram of select internal circuitry of another embodiment of the example EDS depicted in FIG. 1A.

FIG. 2 is a schematic diagram of an example product code matrix that illustrates error detection and the generation of test patterns by the EDS depicted in FIG. 1A, in accordance with one embodiment of the invention.

FIG. 3 is a schematic diagram of the example test pattern matrix illustrated in FIG. 2, which is used by the EDS depicted in FIG. 1A to provide candidate codewords, in accordance with one embodiment of the invention.

FIG. 4A is a table that illustrates an example efficient syndrome calculation method implemented by the EDS of FIG. 1A to decode the test pattern matrix depicted in FIG. 3, in accordance with one embodiment of the invention.

FIG. 4B is a schematic diagram that illustrates the “tree-structure” of the example efficient syndrome calculation method depicted in FIG. 4A, in accordance with one embodiment of the invention.

FIG. 5 is a schematic diagram of an example test pattern matrix with parity bits appended, which are processed by the EDS depicted in FIG. 1A using efficient decoding methods, in accordance with one embodiment of the invention.

FIG. 6 is a table that illustrates an example efficient parity calculation method performed by the EDS of FIG. 1A on the example test pattern matrix depicted in FIG. 5, in accordance with one embodiment of the invention.

FIG. 7A is a table that illustrates an example efficient metric calculation method to generate extrinsic information, in accordance with one embodiment of the invention.

FIG. 7B is a schematic diagram that illustrates the “tree structure” of the example efficient metric calculation method depicted in FIG. 7A, in accordance with one embodiment of the invention.

FIGS. 8 and 9 are tables that illustrate how the example syndrome, parity, and metric calculation methods depicted in FIGS. 4-7 improve upon current turbo product code calculation methods, in accordance with one embodiment of the invention.

### DETAILED DESCRIPTION OF THE PREFERRED EMBODIMENTS

The preferred embodiments of the invention now will be described more fully hereinafter with reference to the accompanying drawings. One way of understanding the preferred embodiments of the invention includes viewing them within the context of a communication system, and more particularly within the context of an efficient decoding system (EDS) that includes functionality for efficient decoding of product codes. Herein, decoding will be understood to include error detection and/or error correction functionality. Although other systems with data transmitted, or transferred, in other formats are considered to be within the scope of the preferred embodiments, the preferred embodiments of the invention will be described in the context of an efficient decoder of the EDS that receives symbols preferably encoded in a turbo product code (TPC) in a matrix format over a communication medium as one example implementation among many.

The symbols include data encoded at one or more encoders. The symbols can be formatted in several forms, including in bit or byte formats, or preferably as real numbered values. Generally, the TPCs described herein will preferably include those formats exhibiting characteristics that include some form of error correction or control code iteration, some mechanism for gathering extrinsic information (e.g., information that can be used to determine the reliability of one or more symbol values), and some form of diversity (e.g., independence in row and column decoding operations).

The preferred embodiments include efficient decoding methods for product codes, such as TPCs. The efficient decoding methods have substantially no performance degradation when compared to current decoding methods and reduce the complexity of current decoders by about an order of magnitude. As described above, although the efficient decoding methods can be applied to product codes in virtually any format, the focus of the below description will be on extended BCH codes as the constituent row and column codes due to their already low-complexity. Therefore, efficient decoding methods include a reduction of decoding complexity for these types of TPCs, but are certainly adaptable to other types of product codes with linear block constituent codes.

Because the preferred embodiments of the invention can be understood in the context of a communications system, an initial general description of a communications system is followed by example hardware and software implementations for the EDS. Following the description of the EDS embodiments is a discussion with accompanying figures pertaining to three efficient decoding methods that can be implemented by the efficient decoder of the EDS, followed by performance comparisons between the three decoding methods and some prior art methodologies.

The efficient decoding methods of the preferred embodiments are presented in which syndromes, even parities, and extrinsic metrics are obtained with a relatively small number of operations. Furthermore, a method is provided among the efficient decoding methods of the preferred embodiments for simplifying the weight and reliability factors typically used by turbo product code decoding algorithms.

The preferred embodiments of the invention may, however, be embodied in many different forms and should not be construed as limited to the embodiments set forth herein; rather, these embodiments are provided so that this disclosure will be thorough and complete, and will fully convey the scope of the invention to those having ordinary skill in the art. Furthermore, all “examples” given herein are intended to be non-limiting, and are provided as an exemplary list among other examples contemplated but not shown.

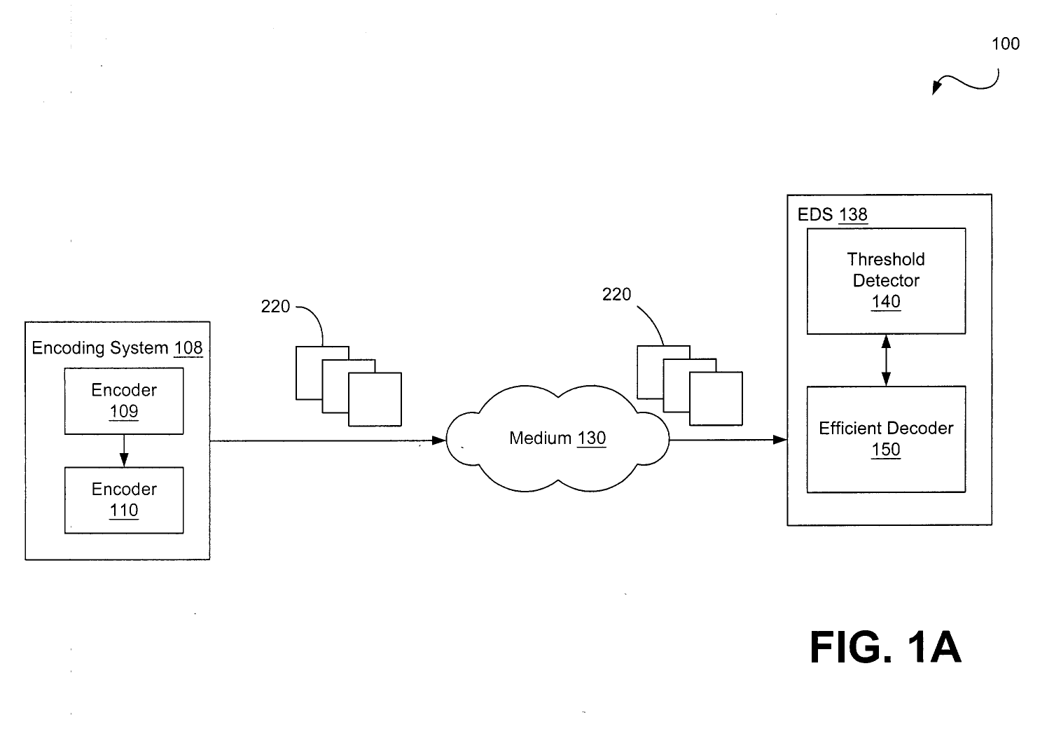

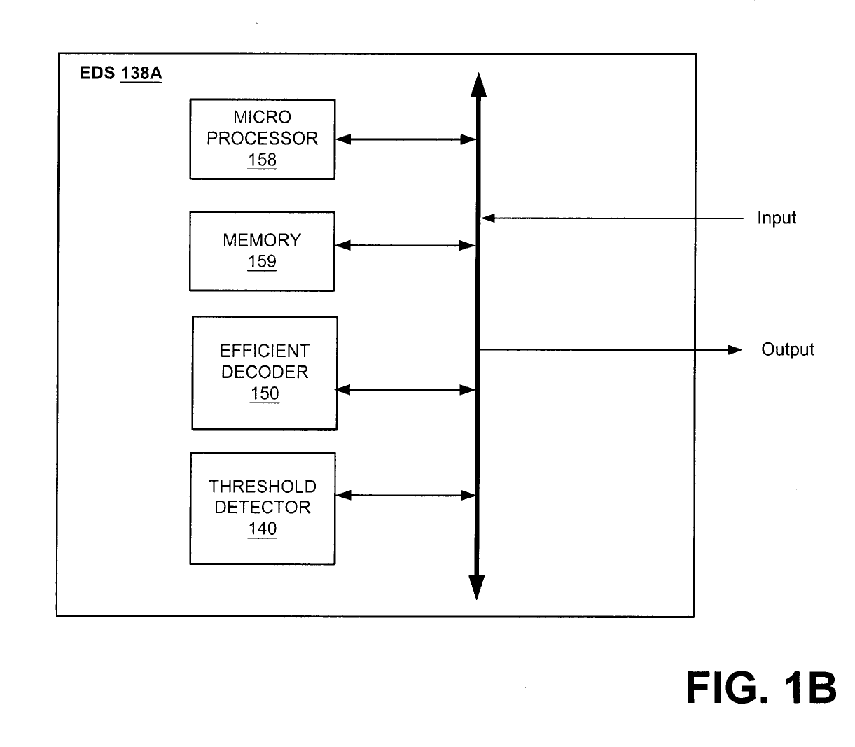

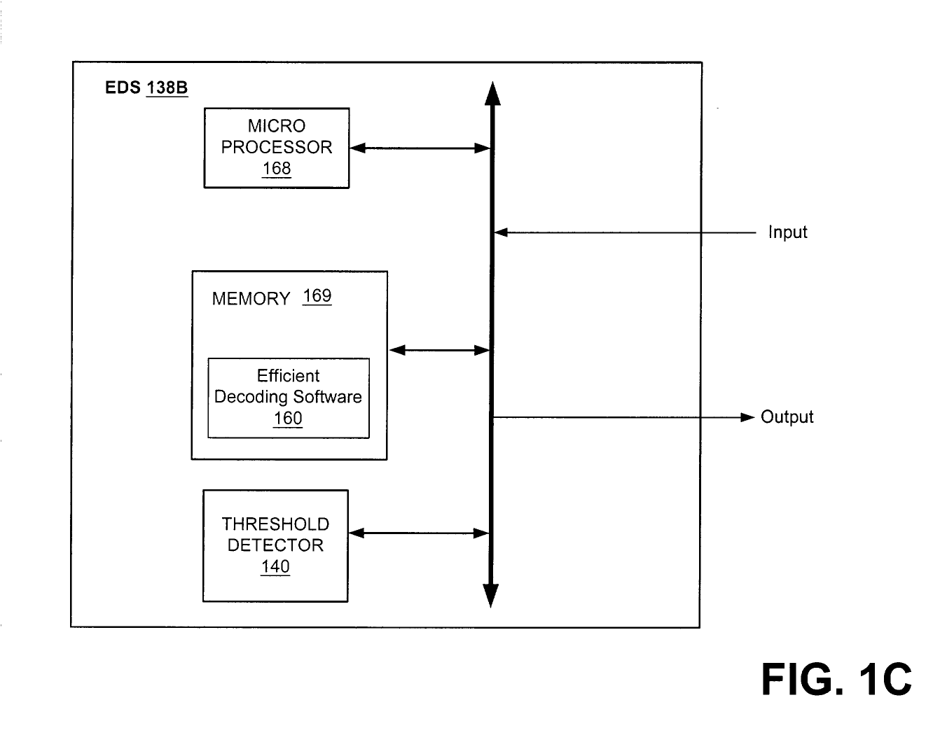

FIG. 1A is a block diagram of one example communication system 100 that employs error correction coding, in accordance with one embodiment of the invention. The example communication system 100 can be implemented as a cable or satellite communication system, or a fiber optic link, or a cellular phone system, among other systems. For example, the communication system 100 can also include systems embodied in a single device, such as a consumer electronics device like a digital video disk (DVD) player, a compact disk (CD) player, or a memory array structure, among other devices, where the communication can occur over an internal bus or wiring between components that include encoding and decoding functionality. As shown, the example communication system 100 includes an encoding system 108, a communication medium 130, and an efficient decoding system (EDS) 138.

The encoding system 108 preferably includes functionality for encoding symbols for transmittal, or transfer, over a communication medium 130, and can be included in such diverse components as a transmitter in a telephone system or in a fiber optic link, or a headend or hub in a cable television system, among other types of systems and devices. The communication medium 130 includes media for providing a conduit for transferring information over a finite distance, including free space, fiber optics, hybrid fiber/coax (HFC) networks, cable, or internal device wiring, among others. The EDS 138 preferably includes functionality for decoding the information transferred over the communication medium 130, and can be included in such devices as a receiver, a computer or set-top box, or other systems or devices that include decoding functionality.

The encoding system 108 preferably includes functionality to encode data for transfer over the communication medium 130, such as encoders 109 and 110. Generally, information is encoded at encoder 109 with a first level of error correction information (e.g., parity). This information and parity can be ordered into a defined format, or in other embodiments, preferably randomized at encoder 109 and then passed to a second encoder 110 where it is encoded with another level of parity, and then output to the communication medium 130. Herein, this information that is encoded and output to the communication medium 130 will be described as a product code 220, the turbo product code being a special case of the product codes 220 wherein extrinsic information is shared between row and column decoders (not shown). The product codes 220 will be described herein using a matrix format (e.g., rows and columns of symbols), with the understanding that product codes will not be limited to this matrix format but can take the form of substantially any encoded format used for transferring data, whether formatted in ordered and/or random fashion.

The EDS 138 preferably includes an efficient decoder 150 and a threshold detector 140, in accordance with one embodiment of the invention. Although shown as separate components, functionality of each component can be merged into a single component in some embodiments. The efficient decoder 150 preferably includes functionality for implementing the efficient decoding methods described herein, in accordance with one embodiment of the invention. The efficient decoder 150 preferably receives the information in product codes 220 transferred over the communication medium 130 (i.e., data is sent over the communication medium 130 usually in a serial fashion. For example, symbols (e.g., bits) are read out row-by-row, or column-by-column. At the EDS side, the efficient decoder 150 re-orders the data into the matrix form). In one example implementation, information can be transferred over the communications medium 130 as symbols formatted as voltage values representing binary 1's and 0's. These voltage values are preferably inserted into the product codes 220 at the encoders 109 and 110. The information is transferred over the communication medium 130 and received, in one implementation, at the efficient decoder 150.

The efficient decoder 150 preferably comprises row and column decoders (not shown) that decode the rows and columns of the product codes 220 and use the information from the communication medium 130 in cooperation with one or more threshold detectors, such as threshold detector 140, to provide efficient error correction of the information, in accordance with the preferred embodiments of the invention. In one implementation, the threshold detector 140 performs a comparator function where it compares the voltage values received at the efficient decoder 150 to a defined threshold value to provide the efficient decoder 150 with an indication of the proximity of the voltage value to a decided binary value (as decided by the efficient decoder 150). In other implementations, the threshold detector 140 performs more of a “threshold” function, where it receives the product codes 220 that have symbols formatted as real numbered values (e.g., voltage values) from the communication medium 130. In this implementation, the threshold detector 140 “thresholds” the received values to bit or byte values, and the efficient decoder 150 operates on these values.

Preferably, the efficient decoder 150 and the threshold detector 140 will operate using a combination of real numbered values and byte and/or bit values during the various stages of decoding. For example, the product codes 220 can carry real numbered voltage values, which are received by the efficient decoder 150. These values can be loaded into the threshold detector 140, which then returns bit values, some of which are “flagged” as unreliable by the efficient decoder 150. The efficient decoder 150 can run error correcting iterations on the bits to provide an update on the reliability of the bits, then use the threshold detector 140 (or another threshold detector) to return the values to updated real numbered values to pass on to a next decoding stage. Note that other components, although not shown, can also be included in the communication system 100 and its various components, including memory, modulators and demodulators, analog to digital converters, processor, among others as would be understood by one having ordinary skill in the art.

FIGS. 1B-1C are block diagram illustrations of select components of the EDS 138 of FIG. 1A, in accordance with two embodiments of the invention. FIG. 1B illustrates the EDS 138A in which the efficient decoder 150 is implemented as hardware, in accordance with one embodiment. The efficient decoder 150 can be custom made or a commercially available application specific integrated circuit (ASIC), for example, running embedded efficient decoding software alone or in combination with the microprocessor 158. That is, the efficient decoding functionality can be included in an ASIC that comprises, for example, a processing component such as an arithmetic logic unit for handling computations during the decoding of rows and columns. Data transfers to and from memory 159 and/or to and from the threshold device 140 for the various matrices (as explained below) during decoding can occur through direct memory access or via cooperation with the microprocessor 158, among other mechanisms. The microprocessor 158 is a hardware device for executing software, particularly that stored in memory 159. The microprocessor 158 can be any custom made or commercially available processor, a central processing unit (CPU), an auxiliary processor among several processors associated with the efficient decoder 150, a semiconductor based microprocessor (in the form of a microchip or chip set), a macroprocessor, or generally any device for executing software instructions. The threshold detector 140 can be software and/or hardware that is a separate component in the EDS 138A, or in other embodiments, integrated with the efficient decoder 150, or still in other embodiments, omitted from the EDS 138 and implemented as an entity separate from the EDS 138 yet in communication with the EDS 138. The EDS 138 can include more components or can omit some of the elements shown, in some embodiments.

In one preferred embodiment, where the efficient decoder 150 is implemented as hardware, the efficient decoder 150 can be implemented with any or a combination of the following technologies, which are each well known in the art: a discrete logic circuit(s) having logic gates for implementing logic functions upon data signals, an ASIC having appropriate combinational logic gates, a programmable gate array(s) (PGA), a field programmable gate array (FPGA), etc.

FIG. 1C describes another embodiment, wherein efficient decoding software 160 is embodied as a programming structure in memory 169, as will be described below. The memory 169 can include any one or combination of volatile memory elements (e.g., random access memory (RAM, such as DRAM, SRAM, SDRAM, etc.)) and nonvolatile memory elements (e.g., ROM, hard drive, tape, CDROM, etc.). Moreover, the memory 169 may incorporate electronic, magnetic, optical, and/or other types of storage media. Note that the memory 169 can have a distributed architecture, where various components are situated remote from one another, but can be accessed by the microprocessor 168.

In one implementation, the software in memory 169 can include efficient decoding software 160, which provides executable instructions for implementing the matrix decoding operations. The software in memory 169 may also include one or more separate programs, each of which comprises an ordered listing of executable instructions for implementing logical functions and operating system functions such as controlling the execution of other computer programs, providing scheduling, input-output control, file and data management, memory management, and communication control and related services.

With continued reference to FIG. 1B, when the EDS 138 (138A or 138B) is in operation, the microprocessor 158 (or 168) is configured to execute software stored within the memory 159 (or 169), to communicate data to and from the memory 159 (or 169), and to generally control operations of the EDS 138A, 138B pursuant to the software.

When the efficient decoding functionality is implemented in software, it should be noted that the efficient decoding software 160 can be stored on any computer readable medium for use by or in connection with any computer related system or method. In the context of this document, a computer readable medium is an electronic, magnetic, optical, or other physical device or means that can contain or store a computer program for use by or in connection with a computer related system or method.

The efficient decoding software 160 and/or efficient decoder 150 can be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can store, communicate, propagate, or transport the program for use by or in connection with the instruction execution system, apparatus, or device. The computer readable medium can be, for example but not limited to, an electronic, magnetic, optical, electromagnetic, infrared, or semiconductor system, apparatus, device, or propagation medium.

More specific examples (a nonexhaustive list) of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM, EEPROM, or Flash memory) (electronic), an optical fiber (optical), and a portable compact disc read-only memory (CDROM) (optical). Note that the computer-readable medium could even be paper or another suitable medium upon which the program is printed, as the program can be electronically captured, via for instance optical scanning of the paper or other medium, then compiled, interpreted or otherwise processed in a suitable manner if necessary, and then stored in a computer memory. In addition, the scope of the present invention includes embodying the functionality of the preferred embodiments of the present invention in logic embodied in hardware and/or software configured mediums.

The descriptions that follow (along with the accompanying drawings) will focus on the hardware embodiment (FIG. 1B) wherein the efficient decoding functionality is implemented via the efficient decoder 150 (FIG. 1B) of the EDS 138 (FIG. 1A), with the understanding that efficient decoding functionality will similarly apply when the software embodiment (FIG. 1C) is employed. Further, it will be understood that the efficient decoder 150 preferably acts in cooperation with other elements of the EDS 138 to provide efficient decoding functionality.

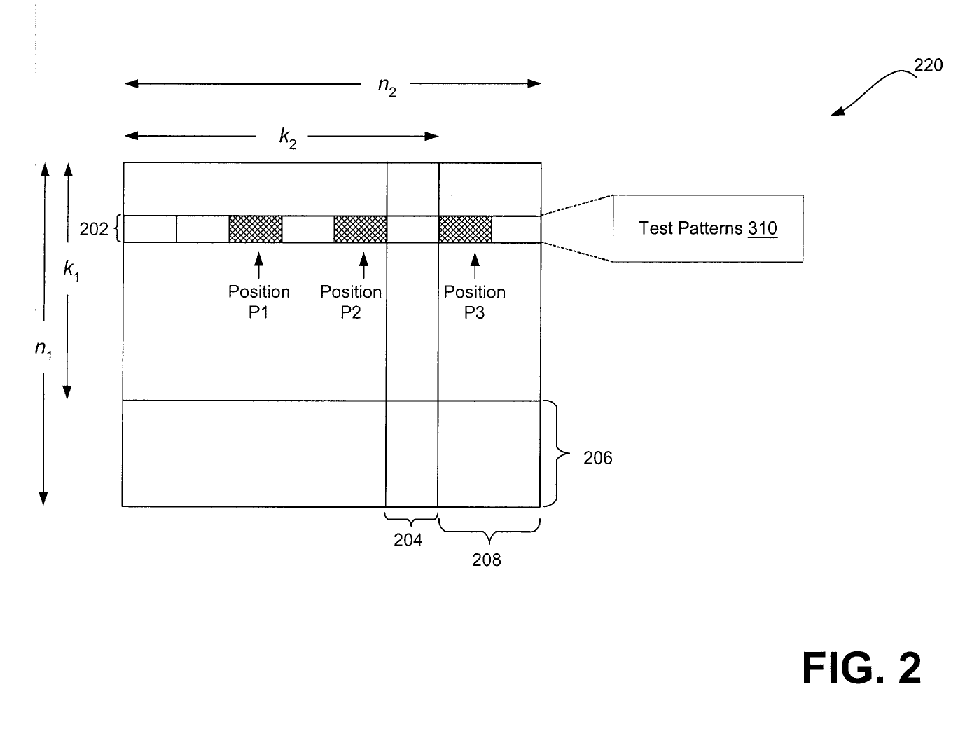

FIG. 2 illustrates the product code 220 received and formatted by the efficient decoder 150 (FIG. 1A), in accordance with one embodiment of the invention. The product codes 220 are preferably configured in a matrix format, and can be represented mathematically. The information symbols are initially arranged in a k₁×k₂ array. Then, the columns 204 (one is shown) are encoded using a linear block code C₁ (n₁, k₁, δ₁), which includes column parity 208. Afterwards, the resulting n₁ rows 202 (one is shown) are encoded using a linear block code C₂ (n₂, k₂, δ₂), including row parity 206, and then the product code 220, which consists of n₁ rows and n₂ columns, is obtained. The parameters of code Cᵢ (i=1,2), denoted as nᵢ, kᵢ, and δᵢ, are the codeword length, number of information symbols, and minimum Hamming distance, respectively. Codes C₁ and C₂ are called the constituent (or component) codes. The parameters of the resultant product code 220 are n_{C}=n₁n₂, k_{C}=k₁k₂, δ_{C}=δ₁δ₂, and the code rate is R_{C}=R₁R₂, where Rᵢ=kᵢ/nᵢ. To decrease implementation complexity, preferably the same block code is selected as the row and column constituent code (i.e., C₁=C₂).

In the discussions of the efficient decoding methods that follow, assume that an extended version of a one-error-correcting binary BCH (n, k, δ) code is used. It will be further understood that further discussion of product codes 220 will include TPCs. Further, although the efficient decoding methods will be described in the context of TPCs with component codes that are extended one-error-correcting BCH codes, the efficient decoding methods of the preferred embodiments can be generalized for and included within the scope of implementations using product codes with substantially any component codes. The code parameters are n=2^{m}−1, k=n−m, δ=3, and m is an integer satisfying m≧2. Let C=c₀c₁ . . . cₙ₋₁ be a codeword of BCH(n, k, δ), where cᵢε{0,1}. Then, the extended version of C is given by C^{ext}=cₑₚc₀c₁ . . . cₙ₋₁, where cₑₚ is the even parity defined as

$${C}_{ep} = [ {\sum }_{i = 0}^{n - 1} {c}_{i} ] mod 2. \qquad ( Eq . 1 )$$

By appending the even parity bit, both the codelength and minimum distance of the code are increased by one and the extended BCH code is denoted as EBCH (n+1, k, δ+1).

If V=vₑₚv₀ . . . vₙ₋₁ is an additive white Gaussian noise (AWGN) vector with components of zero mean and standard deviation σ², then R=rₑₚr₀r₁ . . . rₙ₋₁ is the received vector with rⱼ=vⱼ+(2cⱼ−1). The received hard-decision polynomial is equal to

\overline{y}(x)=y₀+y₁x+y₂x²+ . . . +yₙ₋₁xⁿ⁻¹, (Eq. 2)

with

yⱼ=0, if Λ(yⱼ)≦0, (Eq. 3)

yⱼ=1, if Λ(yⱼ)>0, (Eq. 4)

where the reliability (or log-likelihood ratio (LLR)) of yⱼ is given by Λ(yⱼ)=2rⱼ/σ².

Based at least in part on extrinsic information received from a communications medium (e.g., real numbered voltage values) over which the product codes 220 are transferred, the efficient decoder 150 (FIG. 1A) can “flag” some symbols as unreliable. In other words, after receiving a “noisy” codeword, the efficient decoder 150 detects the p least reliable bit positions. Assume an implementation where the current error detecting/correcting focus of the efficient decoder 150 is on row 202 of the product code 220, and after several iterations, three symbol positions are flagged: positions 1-3. Note that although an implementation will be described wherein p=3, this is one example implementation among many and it will be understood that the efficient decoding methods of the preferred embodiments can be generalized for and considered within the scope of implementations using substantially any integer value of p.

Although emphasis herein will be placed on the row decoding, one skilled in the art will understand that column decoding operating under similar mechanisms to those employed for row decoding will likewise be implemented. Such column decoding can be implemented in a sequential manner (i.e., after the row decoding) or in other embodiments, parallel to the row decoding. Column decoding will include the p least reliable bit positions in the columns, and as described below, the generation of test patterns, and the evaluation of candidate codewords and the subsequent production of valid codewords and extrinsic information, in accordance with one embodiment of the invention. By perturbing, i.e., trying all possible combinations of ones and zeroes in the least reliable bit positions, the efficient decoder 150 (FIG. 1A) will preferably form 2^{p} test patterns (TP) 310 denoted by TPᵢ for i=0, . . . 2^{p}−1, and then employ an efficient syndrome calculation method to determine one or more valid decoded codewords among one or more generated candidate codewords, in accordance with one embodiment of the invention.

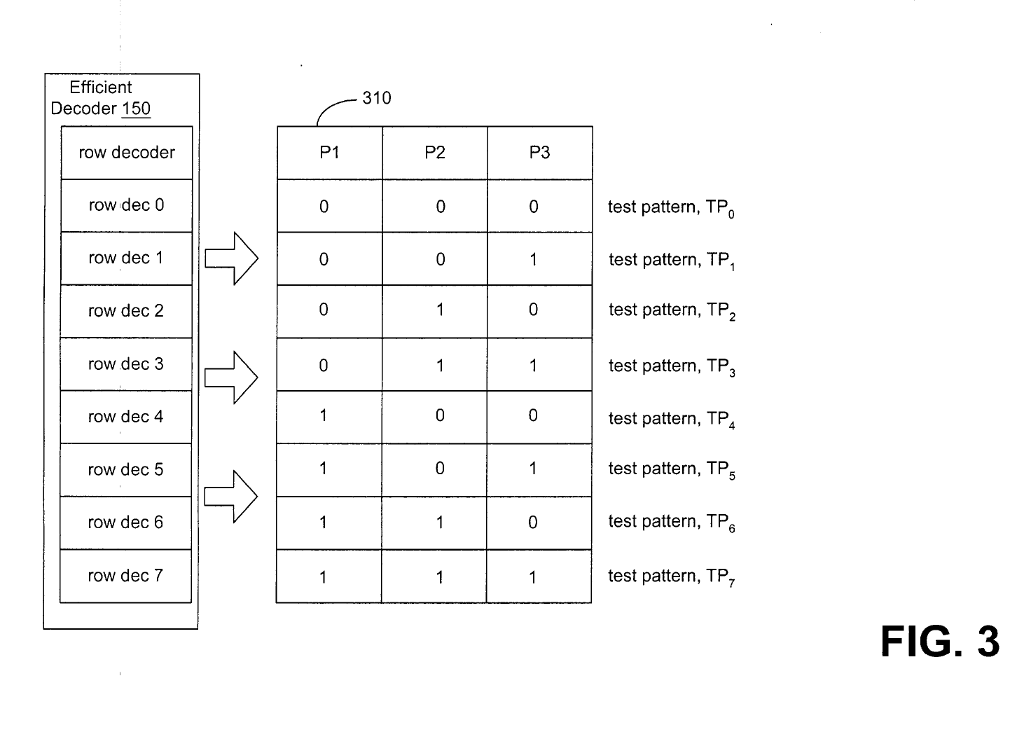

FIG. 3 illustrates some example test patterns 310 generated by the efficient decoder 150 for decoding via row decoders 0-7 of the efficient decoder 150, in accordance with one embodiment of the invention. Note that the efficient decoder 150 can include one or more row and column decoders. In this example, 8 row decoders are shown, with the understanding that more or fewer can be employed. These TPs 310 are obtained by identifying and perturbing the p least reliable components yⱼ₀, yⱼ₁, . . . yⱼₚ₋₁. Symbols that are reliable (i.e., symbols at positions other than P1-3) (not shown) will preferably be thresholded and fixed at their respective 0 or 1 bit value, and 2^{p} test patterns will be generated and passed through the efficient decoder 150, which will employ an efficient syndrome calculation method to obtain codeword candidates Ĉⁱ, in accordance with one embodiment of the invention. Note that the fixed positions are not shown, with the understanding that the entire transferred codeword along with the error positions are included in the test patterns 310. In other words, each of the TPs 310 not only includes the p least reliable bit positions, but n bit positions per test pattern (i.e., the p least reliable bit positions and the fixed bit positions that are reliable). Further, it will be noted that although there are n bit positions in a test pattern, the test patterns may differ only in p positions, as illustrated in FIG. 3. This fact will be exploited by the even parity calculation method of the preferred embodiments, as described below.

A syndrome is a mathematical calculation preferably computed by the efficient decoder 150 to find errors in the transferred codewords. There is a 1:1 relationship between an error and a syndrome. For example, if there is an error in the first position, there is a syndrome s₀ corresponding with that error. If there is an error in the second position, there is a corresponding syndrome s₁, and so on. In other words, if there were 16 bit positions, there would be 16 distinct syndromes that, when they occur, provide an indication of an error in a particular bit position. Continuing, if the decoder corrects a single error, the error patterns result in different syndromes. Conversely, if a syndrome is calculated for a particular bit position, then it reflects an error in that particular position. Thus, syndromes can be used to find an error pattern.

Recall from FIGS. 2 and 3 that unreliable symbols were detected in a row, and thus the row was the focus of test patterns formed for the three unreliable positions (and as indicated above, a similar process occurs during column decoding). The bit value in the j^{th} position of the expanded row is referred to as cⱼ, and α is referred to as an abstract quantity in a finite field. Then, for row decoder 0 of the efficient decoder 150, the syndrome for the j^{th} bit of row 0 can be calculated as,

$${s}_{0} = {\sum }_{j = 0}^{n - 1} {c}_{j}^{0} {α}^{j} \qquad ( Eq . 5 )$$

Similarly, for row decoder 1, the syndrome can be calculated as,

$${s}_{1} = {\sum }_{j = 0}^{n - 1} {c}_{j}^{1} {α}^{j} \qquad \text{(Eq. 6)}$$

Thus the c^{j}ᵢ's (here, where i=0 for Eq. 5 and 1 for Eq. 6) differ in p or possibly more or less bit positions after error correcting of each test pattern. For row 0, these bits are loaded into the row decoder 0 and the syndrome calculation is performed. Similarly, for row decoder 1, the bits of row 1 are loaded and the row decoder 1 performs the syndrome calculation. A zero value for a calculated syndrome preferably provides an indication of a valid codeword. If one of the decodings generate a zero valued syndrome, the zero value will provide an indication that the errors have been corrected for the particular candidate codeword. Note that the syndrome calculation is the same for each row. Further, note from the test pattern matrix of FIG. 3 that test patterns TP₂_{^{b}}₊ₖ and TPₖ differ only in bit position j_{b}. Noting that relationship, a syndrome calculation using the efficient syndrome calculation method for a particular row is preferably some function of the syndrome calculation for a prior row, or rather,

s₁=ƒ(s₀). (Eq. 7)

Thus, the syndrome calculation of the efficient syndrome calculation method can be described by a recursive function, and/or implemented as a “tree” function, among others. Recursive generally includes the idea that the output is not only a function of the inputs (e.g., variable₍ₖ₎), but it also depends on past outputs (e.g., variable₍ₖ₋₁₎).

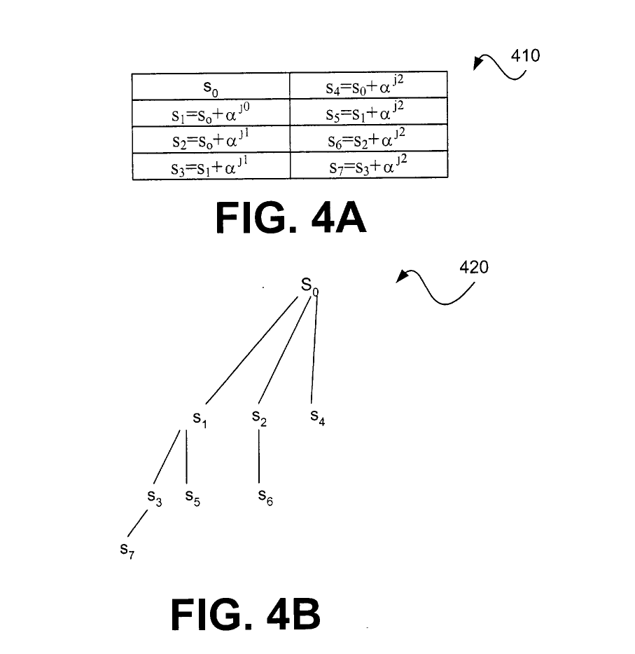

One result of this recursive relationship is that the first row decoder (i.e., row decoder 0), in one embodiment, preferably runs the first multiplication and addition of the first syndrome calculation, and then subsequent operations are a function of the prior operations, as illustrated in the efficient syndrome calculation table 410 shown in FIG. 4A. Note that there is no requirement that the test patterns be re-ordered in a binary tree or a Gray code order to be implemented. This table is also schematically mirrored in the “data tree” structure 420 shown in FIG. 4B. As shown, the efficient decoder 150 (FIG. 1A) preferably implements the efficient syndrome calculation method to replace, what was conventionally a series of multiplication and addition operations, with a single multiplication for the first row, and a single addition for each additional row. The data tree 420 shows this relationship. For example, upon the efficient decoder 150 finding s₀, the syndromes for rows 1,2, and 4 can be recursively determined (i.e., s₁, s₂, and s₄). Similarly, from s₁, the syndromes s₃ and s₅ can be recursively determined, and so on.

This syndrome calculation of the efficient syndrome calculation method of the preferred embodiments can be represented mathematically as follows. For each test pattern TPᵢ, a syndrome Sᵢ is preferably calculated. The syndrome for the first TP is found by evaluating:

S₀=\overline{y}(α)|_{yj0}= . . . =yⱼₚ₋₁=0, (Eq. 8)

where α is a primitive element of GF (2^{m}) (Galois Field) used to determine the generator polynomial of the EBCH code. The syndromes for the remaining 2^{p}−1 TPs can be calculated efficiently using

S₂_{^{b}}₊ₖ=Sₖ+α^{j}^{_{b}}, (Eq. 9)

for b=0, . . . , p−1 and k=0, . . . , 2^{b}−1. The recursive relation given in (Eq. 9) is based on the fact that TP₂_{^{b}}₊ₖ and TPₖ differ only in bit position j_{b}. With this approach, the number of GF (2^{m}) additions required to determine all 2^{p} syndromes is reduced from n2^{p} to n+2^{p-}1. For an EBCH (2^{m}, 2^{m}−1−m, 4) code, the syndrome (if nonzero) indicates the bit error location. Hence, bit ĉⁱ_{Si} is the inverted version of y_{Si} (i.e., ĉⁱsᵢ=(y_{Si}+1) mod 2). In other words, if the syndrome Sᵢ is nonzero, it provides an indication of an error at the Sᵢ^{th} bit location, and thus that bit position is flipped (or inverted) to correct the error.

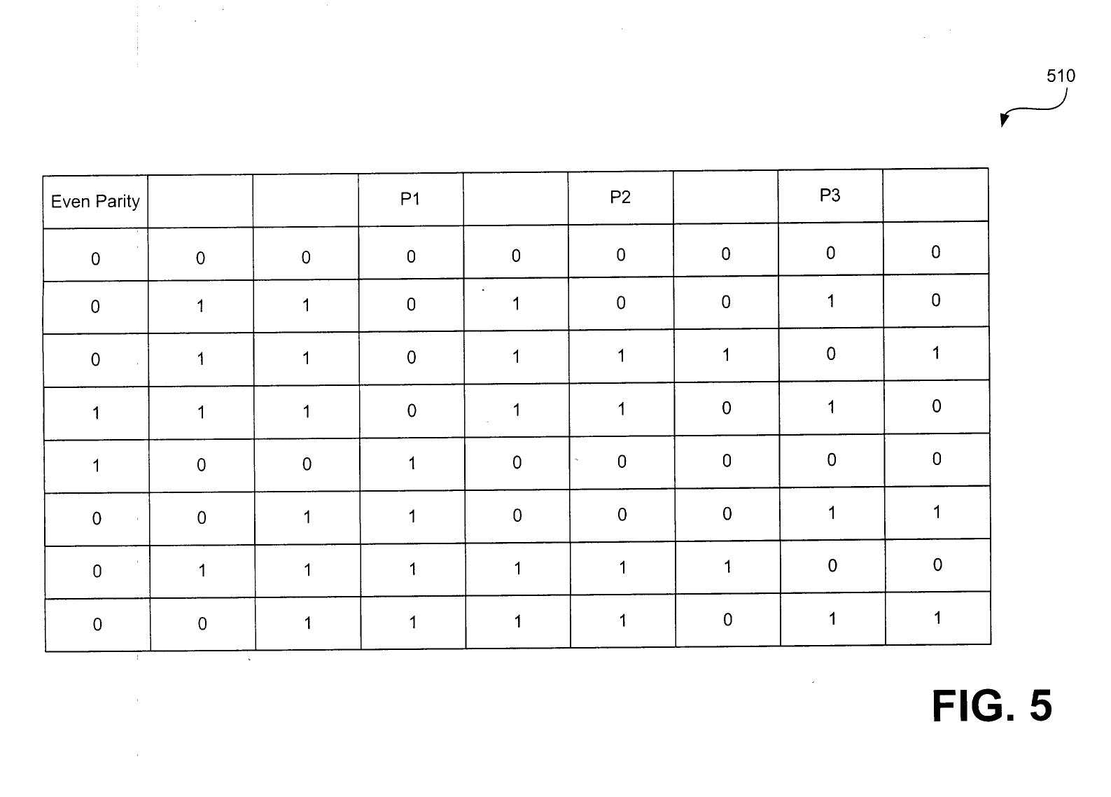

Once the error locations are found, the even parities are preferably determined for all candidate codewords. The parity of these candidate codewords can be calculated in an effort to reduce the list of candidates. In one implementation, the list of candidates can be reduced by comparing the parity of the candidates with the parity of the received codeword. For example, candidates with a parity that does not match the parity of the received codeword can be rejected as invalid candidates, while retaining the other candidate codewords. Note that in other implementations, all candidate codewords may be retained. FIG. 5 is an illustration of candidate codewords in table 510 resulting from a row decoding that have an added parity bit tacked on to indicate whether there is even (bit value of 0) or odd (bit value of 1) parity, in accordance with an embodiment of the invention. There are several ways to reach this point.

One conventional mechanism for determining parity includes doing a modulo-2 addition of all of the bit positions to decide whether the candidate codeword has even or odd parity. With the below efficient parity calculation method as implemented by the efficient decoder 150 (FIG. 1A), the parity calculations can be determined recursively, thus reducing the total number of modulo-2 additions for determining the 2^{p} even parities from n2^{p} using conventional methods to n−p+1+2^{p}. In one embodiment, the even parity calculation is preferably done using all of the n bit positions of the candidate codewords. The even parity for each test pattern can be calculated by the efficient decoder 150 in terms of ƒₑᵥₑₙ and ƒ_{odd}, defined as

$${f}_{even} = [ {\sum }_{j \neq jq … , jp - 1} {y}_{i} ] mod 2 , \qquad \text{(Eq. 10)}$$

and

ƒ_{odd}=[ƒₑᵥₑₙ+1] mod 2, (Eq. 11)

Then, the even parity for the TPs can be found by,

ĉⁱₑₚ=[ƒₑᵥₑₙ+Ω(Sᵢ)] mod 2, for TPs with even number of 1's, (Eq. 12a)

ĉⁱₑₚ=[ƒ_{odd}+Ω(Sᵢ)] mod 2, for TPs with odd number of 1's, (Eq. 12b)

where Ω(Sᵢ) is defined as,

Ω(Sᵢ)=1, if Sᵢ≠0, (Eq. 13a)

Ω(Sᵢ)=0, if Sᵢ=0. (Eq. 13b)

In order to identify the TPs with even and odd number of 1's, the following method is used. Let

$${ϕ}_{k}^{even} and {ϕ}_{k}^{odd}$$

denote the sets of TP indices with even and odd number of 1's in the p perturbed positions, respectively.

$${ϕ}_{k}^{even} and {ϕ}_{k}^{odd}$$

are tools employed by the efficient parity calculation method to partition the TPs into two groups to enable the functions ƒₑᵥₑₙ and ƒ_{odd} to find the even parity of the n bit positions of the candidate codewords, since one goal of the efficient decoder 150 (FIG. 1A) is to find the even parities for all candidate codewords with the help of ƒₑᵥₑₙ and ƒ_{odd}. Specifically, the TPs with indices in

$${ϕ}_{k}^{even}$$

use ƒₑᵥₑₙ to find the overall parity for the candidate codewords, and similarly, the TPs with indices in

$${ϕ}_{k}^{odd}$$

use ƒ_{odd} to find the overall parity for the candidate codewords. If there are p least reliable bit positions, then

$${ϕ}_{p - 1}^{even} and {ϕ}_{p - 1}^{odd}$$

have to be found. Preferably, the implementation starts with the initial conditions

$${ϕ}_{0}^{even} = \{ 0 \} and {ϕ}_{0}^{odd} = \{ 1 \} .$$

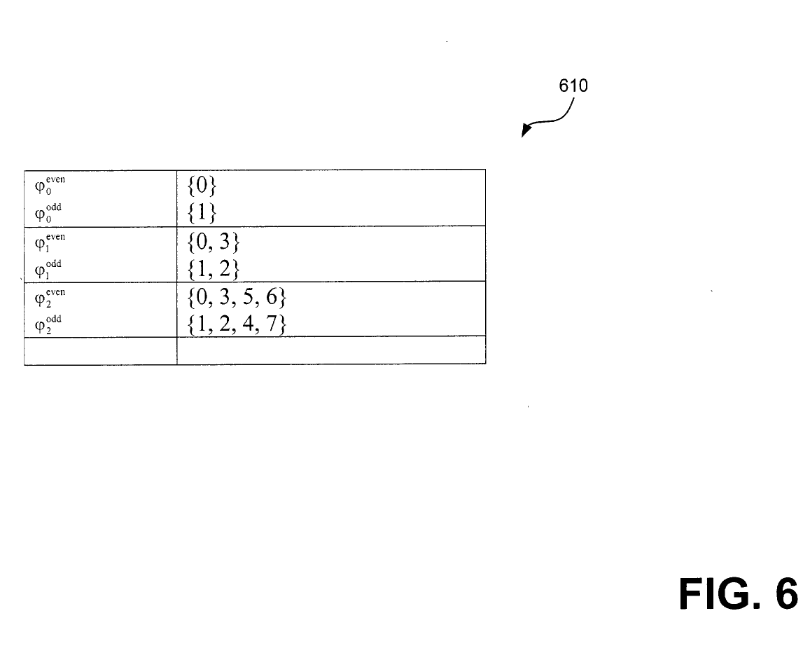

The remaining sets are determined recursively by,

$${ϕ}_{0}^{even} = \{ 0 \} and {ϕ}_{0}^{odd} \{ 1 \} .$$

where k=1,2, . . . , p−1, and φ ⊕ z denotes the operation where the integer z is added to each element of set φ. Using the above approach, the calculations for p=3 are illustrated in table 610 in FIG. 6, with the result that

$${ϕ}_{3}^{even} = \{ 0 , 3 , 5 , 6 \} and {ϕ}_{3}^{odd} = \{ 1 , 2 , 4 , 7 \}$$

which is consistent with the TP indices in FIG. 3. Depending on p, these indices can be determined once and then stored in the efficient decoder 150 (FIG. 1A). Therefore, these calculations do not create an overhead in the implementation of this efficient parity calculation method.

After decoding the TPs, a metric is calculated for each candidate codeword Ĉⁱ. A metric includes the relation between the received noisy sequence (e.g., voltage values) and candidate codewords. The efficient metric calculation method described below is based in part on the Euclidean distance metric, but it can be adapted easily to other types of metrics as well. The squared Euclidean distance metric includes a description of the distance between the received noisy sequence and the candidate codeword. That is, the closer the candidate codeword and received noisy sequence are, the smaller is the squared Euclidean distance metric between them. One goal of a Chase type decoder is to find the most likely codeword (i.e., the candidate codeword with the minimum squared Euclidean distance to the received sequence). Note that the Euclidean distance metric used in determining the reliability for TPCs involve some very complex operations. For example, if the decoding occurs over the length of 16 bits, then that is 16 subtractions, 16 squarings, and then summations of all the squares. These operations are typically performed for each bit in each row (as well as each bit for each column). A more detailed analysis of TPC decoding and operations using the Euclidean distance metric to determine the reliability of candidate codewords can be found in the reference entitled “Near-optimum decoding of product codes: “Block turbo codes,” IEEE Trans. Commun., vol. 46, no. 8, pp. 1003-1010, August 1998, and the patent entitled, “Process for Transmitting Information Bits with Error Correction Coding and Decoder for the Implementation of this Process, having U.S. Pat. No. 6,122,763, filed Aug. 28, 1997, all of which are herein incorporated by reference.

In contrast to the conventional methodologies alluded to in part of the above paragraph, the computational burden of the efficient metric calculation method will fall primarily on the determination of a partial metric, h₀, and then subsequent operations will be a function of h₀ and its progeny. The squared Euclidean distance between received vector R and candidate codeword Ĉⁱ is defined as

Lᵢ=|R−Ĉⁱ|² (Eq. 16a)

$$\begin{matrix}{L}_{i} = {\vert R - {\hat{C}}^{1} \vert}^{2} & ( Eq . 16 a ) \\ = {[ {r}_{ep} - ( {{2}^{\hat{}}}_{ep}^{i} - 1 ) ]}^{2} + {\sum }_{v = 0}^{n - 1} {[ {r}_{v} - ( {2}_{v}^{i} - 1 ) ]}^{2} & ( Eq . 16 b ) \\ = n + 1 - 2 {l}_{i} + {r}_{ep}^{2} + {\sum }_{v = 0}^{n - 1} {r}_{v}^{2} . & ( Eq . 16 c )\end{matrix}$$

The metric lᵢ in (Eq. 16c) is called the inner product of R and Ĉⁱ and is defined as

lᵢ=R·Ĉⁱ=rₑₚ(2ⁱₑₚ−1)+uᵢ, (Eq. 17)

where uᵢ denotes the updated metric and is equal to

$${u}_{i} = {\sum }_{v = 0}^{n - 1} {r}_{v} ( {2}_{v}^{i} - 1 ) , \qquad ( Eq . 18 )$$

Note that all the terms in (Eq. 16c) except −2lᵢ are constants, which means that minimizing Lᵢ is equivalent to maximizing lᵢ. Hence, one decision criterion for the efficient decoder 150 (FIG. 1A) is to choose the candidate codeword with the maximum lᵢ as the decoded codeword. For efficient decoding, the inner product metric lᵢ is preferably used instead of the squared Euclidean distance metric Lᵢ, since the former requires fewer operations. Hence, one focus is on finding an efficient calculation method for lᵢ's.

For each candidate codeword, a partial metric hᵢ can be introduced, where hᵢ for i=0 is given by

$${h}_{0} = {\sum }_{v = 0}^{n - 1} {r}_{v} ( 2 {y}_{v} - 1 ) {ly}_{j0} = … = {y}_{jp - 1} = 0. \qquad ( Eq . 19 )$$

Note that

rᵥ(2yᵥ−1)=−rᵥ, if yᵥ=0, (Eq. 20a)

rᵥ(2yᵥ−1)=+rᵥ, if yᵥ=1 (Eq. 20b)

This has the following effect: When position yᵥ is switched from 0 to 1, then 2rᵥ is added to the metric. On the other hand, if yᵥ is switched from 1 to 0, then 2rᵥ is subtracted from the metric. Hence, for the remaining TPs, the hᵢ's are found recursively using

h₂_{^{b}}₊ₖ=hₖ+2r_{jb}, (Eq. 21)

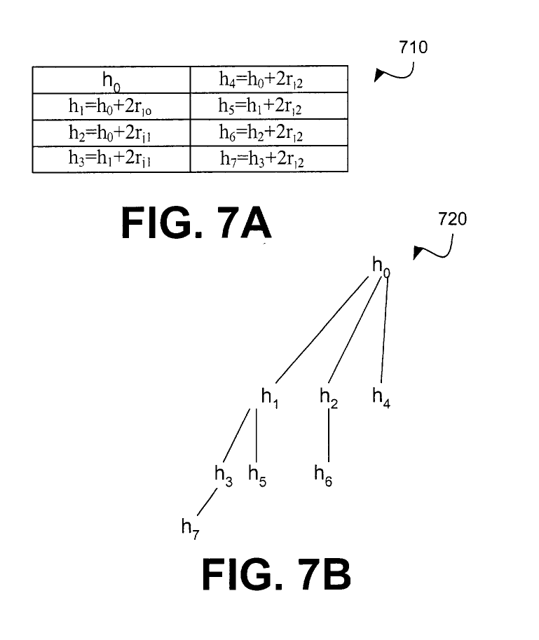

for k=0, . . . , 2^{b}−1 and b=0, . . . p−1. The recursive relation in (Eq. 21) is obtained by the fact that bit position j_{b} is switched from 0 to 1 if considering TPₖ and TP₂_{^{b}}₊ₖ. For example, the calculation of hᵢ's for the p=3 case are as shown in the table 710 depicted in FIG. 7A, with the corresponding “tree” structure 720 in FIG. 7B. Thus, the efficient metric calculation method can include, but is not restricted to, a tree-type implementation and/or a recursive function implementation, among others.

The hᵢ is called a partial metric, since it does not contain the information if the codeword candidate Ĉⁱ had a nonzero syndrome and was updated or not. The syndrome information is actually included in the updated metric uᵢ, which is obtained by applying

uᵢ=hᵢ, if Sᵢ=0, (Eq. 22a)

uᵢ=hᵢ−2(2y_{Si}−1)r_{Si}, if Sᵢ≠0. (Eq. 22b)

The calculation of uᵢ in (Eqs. 22a,b) is also based on (Eqs. 20a,b). That is, depending on the syndrome and hard-decision y_{Si}, 2r_{Si} is either added to or subtracted from the partial metric hᵢ. The updated metric uᵢ is then used in (Eq. 17) to obtain the inner product lᵢ. Finally, the candidate codeword with the highest lᵢ value is preferably designated as the decoded codeword by the efficient decoder 150 (FIG. 1A). With the above efficient metric calculation method, the number of operations (i.e., total number of floating point additions) to determine all 2^{p} lᵢ's is reduced from n2^{p} to 5(2^{p})+n−2. If inner products are applied instead of squared Euclidean distances, then it can be shown that the LLR can be evaluated as

Λ(dⱼ)=[(R·D−R·\hat{D})/2](2dⱼ−1). (Eq. 23)

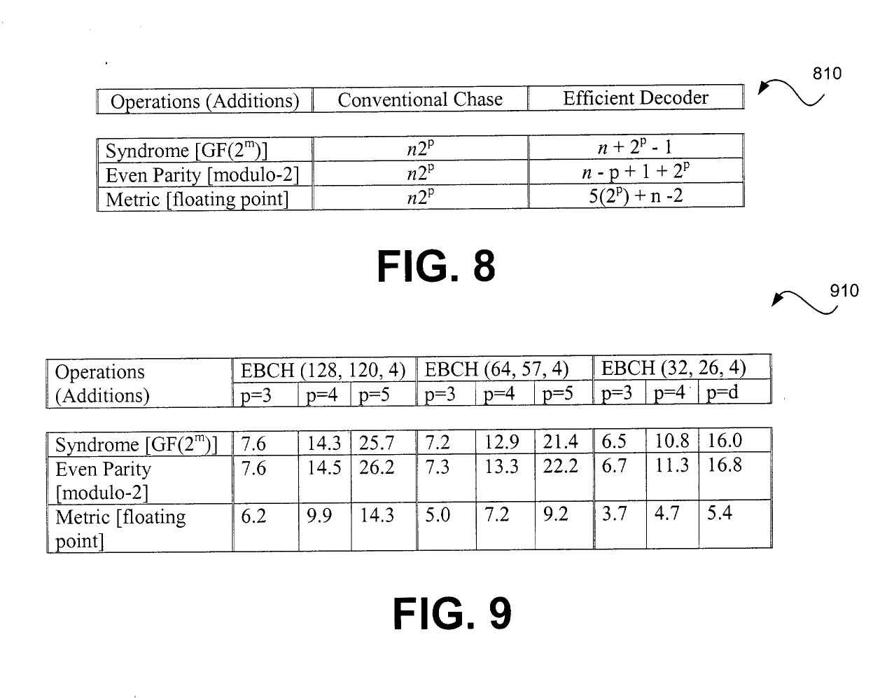

In order to compare the complexity of the efficient decoding methods of the preferred embodiments with the prior art TPC decoding methods, the number of operations and the ratios of the number of operations implemented by both methods for several p values and different types of EBCH codes are given in Table 810 and Table 910, respectively, as shown in FIGS. 8 and 9. Table 810 of FIG. 8 shows that the efficient decoding methods of the preferred embodiments can reduce the number of operations when compared to prior art methods. Table 910 of FIG. 9 provides a complexity ratio, defined as the number of operations of the prior art methods over the number of operations performed by the efficient decoding methods of the preferred embodiments. As shown in Table 910, it is revealed that for p values, especially for larger p values, decoding complexity is significantly reduced with the efficient decoding methods. For example, the EBCH (128,120,4) efficient decoding with p=5 has 25.7, 26.2 and 14.3 times less complexity for syndrome, even parity and metric calculations, respectively. If code rate and decoding complexity is considered, it appears that efficient decoding of the EBCH (64,57,4) code with p=4 would have about 8 times less complexity for the overall number of operations. BER performances (not shown) of the efficient decoding methods do not indicate any significant degradation in performance when compared to prior art TPC decoding. This is due in part to the fact that no approximations are used during the implementation of the efficient decoding methods.

Note that a further decrease in complexity can be realized by the efficient decoder 150 (FIG. 1A) being configured with the weight and reliability parameters equal to a constant for all iterations, in accordance with an embodiment of the invention. For example, one efficient decoding method that can be employed includes setting the constants to

γ=0.5 (Eq. 24)

and

β=1. (Eq. 25)

Observations confirm that normalization of extrinsic information can be avoided without significant performance degradation by using the above proposed constant values for the weight and reliability factors. Thus, without normalization of the extrinsic information before passing to the next decoding stage, a less complex decoder for TPCs with different constituent codes can be implemented.

It should be emphasized that the above-described embodiments of the present invention, particularly, any “preferred” embodiments, are merely possible examples of implementations, merely set forth for a clear understanding of the principles of the invention. Many variations and modifications may be made to the above-described embodiment(s) of the invention without departing substantially from the spirit and principles of the invention. All such modifications and variations are intended to be included herein within the scope of this disclosure and the present invention and protected by the following claims.

Therefore, having thus described the invention, at least the following is claimed:

1. A method for decoding product codes, said method comprising the steps of:
generating syndromes for a first codeword test pattern; and
generating syndromes for subsequent codeword test patterns using a recursive function of the syndromes generated for a codeword test pattern previously generated.

2. The method of claim 1, wherein the step of generating syndromes for the first codeword test pattern includes multiplication and addition operations.

3. The method of claim 1, wherein the step of generating syndromes for the subsequent codeword test patterns includes the operations included in generating the syndromes for the previous codeword test patterns plus one addition operation.

4. The method of claim 1, wherein the step of generating syndromes for the first codeword test pattern includes calculating a result for the equation
$${s}_{0} = {\sum }_{j = 0}^{n - 1} {c}_{j}^{0} {α}^{j} ,$$
wherein cⱼ⁰ is the bit value in a jth position in a test pattern codeword, wherein j is an integer value at least equal to zero, wherein α^{j} is an abstract quantity in a finite field.

5. The method of claim 4, wherein the step of generating syndromes for the subsequent codeword test pattern includes calculating a result for the equation S₂b₊ₖ=Sₖ+α^{j}^{^{b}}, wherein b=0, . . . , p−1 and k=0, . . . , 2^{b}−1, wherein p is the amount of bit errors that are targeted for correction, wherein test patterns (TP) TP₂_{^{b}}₊ₖ and TPₖ differ only in bit position j_{b}.

6. The method of claim 1, wherein the generating steps include calculating n+2^{p}−1 mathematical operations, wherein n is an integer number and p equals the number of least reliable bits.

7. The method of claim 1, wherein a non-zero value for a syndrome indicates an error position in the codeword test pattern.

8. The method of claim 1, further comprising the step of ordering the test patterns in a 2^{p} binary logic table, wherein p equals the number of least reliable bits, wherein the test patterns are ordered in conventional binary order.

9. A method for decoding product codes, said method comprising the steps of:
generating syndromes for a first codeword test pattern, wherein the step of generating syndromes for the first codeword test pattern includes calculating a result for the equations
$${s}_{0} = {\sum }_{j = 0}^{n - 1} {c}_{j}^{0} {α}^{j} ,$$
wherein cⱼ⁰ is the bit value in a jth position in a test pattern codeword, wherein j is an integer value at least equal to zero, wherein α^{j} is an abstract quantity in a finite field; and
generating syndromes for subsequent codeword test patterns using a recursive function of the syndromes generated a codeword test pattern previously generated, wherein the step of generating syndromes for the subsequent codeword test patterns includes calculating a result for the equation S₂b₊ₖ=Sₖ+α^{j}^{^{b}}, wherein b=0, . . . , p−1 and k=0, . . . , 2^{b}−1, wherein p equals the number of least reliable bits, wherein test patterns (TP) TP₂b₊ₖ and TPₖ differ only in bit position j_{b}.

10. A method for decoding product codes, said method comprising the steps of:
determining an even parity function and an odd parity function for a codeword test pattern, wherein the odd parity function is a function of the even parity function; and
determining an even parity codeword test pattern having an even number of ones from the modulo two of the summation of the even parity function and at least one of a zero and a nonzero syndrome for a jth bit position, wherein j is an integer value at least equal to zero, otherwise
determining an even parity codeword test pattern having an odd number of ones from the modulo two of the summation of the odd parity function and at least one of a zero and a nonzero syndrome for a jth bit position.

11. The method of claim 10, wherein the step of determining an even parity function includes calculating a result for the equation
$${f}_{even} = [ {\sum }_{j \neq jo , , {j}_{p -} 1 }^{} {y}_{i} ]$$
mod 2, wherein p equals the number of least reliable bits, wherein y is a hard decision polynomial of the form \overline{y}(x)=y₀+y₁x+y₂x²+ . . . +yₙ₋₁xⁿ⁻¹.

12. The method of claim 11, wherein the step of determining an odd parity function includes calculating a result for the equation ƒ_{odd}=[|ƒₑᵥₑₙ+1] mod 2.

13. The method of claim 10, wherein the step of determining the even parity codeword test pattern, Ĉⁱₑₚ, having an even number of ones includes calculating a result for the equation Ĉⁱₑₚ=[ƒₑᵥₑₙ+Ω(Sᵢ)] mod 2, wherein Ω(Sᵢ)=1, if Sᵢ≠0, and wherein Ω(Sᵢ)=0, if Sᵢ=0, wherein Sᵢ wherein Sᵢ is a syndrome calculation for the ith test pattern, wherein i is an integer value at least equal to zero.

14. The method of claim 13, wherein the step of determining the even parity codeword test pattern having an odd number of ones includes calculating a result for the equation ĉⁱₑₚ=[ƒ_{odd}+Ω(Sᵢ)] mod 2.

15. The method of claim 10, further including the step of identifying the sets of codeword test pattern indices in perturbed p positions with an even and odd number of ones, wherein p equals the number of least reliable bits.

16. The method of claim 15, wherein the step of identifying further includes the step of recursively determining the remaining sets from an initial first odd set,
$${ϕ}_{0}^{odd} = \{ 1 \} ,$$
and even set,
$${ϕ}_{0}^{even} = \{ 0 \} .$$

17. The method of claim 16, wherein the step of recursively determining includes the step of calculating the result from the equations
$${ϕ}_{k}^{even} = \{ {ϕ}_{k - 1 ,}^{even} {ϕ}_{k - 1}^{odd} ⊕ {2}^{k}$$
and
$${ϕ}_{k}^{odd} = \{ {ϕ}_{k - 1 ,}^{odd} {ϕ}_{k - 1}^{even} ⊕ {2}^{k} \} ,$$
wherein k=1,2, . . . , p−1, and φ ⊕ z denotes the operation where the integer z is added to each element of set φ, wherein
$${ϕ}_{k}^{even} and {ϕ}_{k}^{odd}$$
denote the sets of the codeword test pattern indices in perturbed p positions with even and odd number of 1's, respectively.

18. The method of claim 10, wherein the determining steps include calculating n−p+1+2^{p} mathematical operations, wherein n is an integer number and p equals the number of least reliable bits.

19. A method for decoding product codes, said method comprising the steps of:
determining an even parity function and an odd parity function for a codeword test pattern, wherein the odd parity function is a function of the even parity function, wherein the step of determining an even parity function includes calculating a result for the equation
$${f}_{even} = [ {\sum }_{j \neq jo , … , lp - 1} {y}_{1} ]$$
mod 2, wherein p equals the number of least reliable bits, wherein y is a hard decision polynomial of the form \overline{y}(x)=y₀+y₁x+y₂x²+ . . . +yₙ₋₁xⁿ⁻¹, wherein the step of determining an odd parity function includes calculating a result for the equation ƒ_{odd}=[ƒₑᵥₑₙ+1] mod 2;
determining the even parity codeword test pattern, Ĉⁱₑₚ, having an even number of ones from the modulo two of the summation of the even parity function and at least one of a zero and a nonzero syndrome for a jth bit position, wherein the step of determining the even parity codeword test pattern, Ĉⁱₑₚ, having an even number of ones includes calculating a result for the equation Ĉⁱₑₚ=[ƒₑᵥₑₙ+Ω(Sᵢ)] mod 2, wherein Ω(Sᵢ)=1, if Sᵢ≠0, and wherein Ω(Sᵢ)=0, if Sᵢ=0, wherein Sᵢ wherein Sᵢ is a syndrome calculation for the ith test pattern, wherein i is an integer value at least equal to zero, otherwise
determining the even parity codeword test pattern having an odd number of ones from the modulo two of the summation of the odd parity function and at least one of a zero and a nonzero syndrome for a jth bit position, wherein the step of determining the even parity codeword test pattern having an odd number of ones includes calculating a result for the equation ĉⁱₑₚ=[f_{odd}+Ω(Sᵢ)] mod 2; and
identifying the sets of codeword test pattern indices in perturbed p positions with an even and odd number of ones, wherein the step of identifying further includes the step of recursively determining the remaining sets from an initial first odd set,
$${ϕ}_{0}^{odd} = \{ 1 \} ,$$
and even set,
$${ϕ}_{0}^{even} = \{ 0 \} ,$$
wherein the step of recursively determining includes the step of calculating the result from the equations
$${ϕ}_{k}^{even} = \{ {ϕ}_{k - 1 ,}^{even} {ϕ}_{k - 1}^{odd} ⊕ {2}^{k} and {ϕ}_{k}^{odd} = \{ {ϕ}_{k - 1 ,}^{odd} {ϕ}_{k - 1}^{even} ⊕ {2}^{k} \} ,$$
wherein k=1,2, . . . , p−1, and φ ⊕ z denotes the operation where the integer z is added to each element of set φ, wherein
$${ϕ}_{k}^{even} and {ϕ}_{k}^{odd}$$
denote the sets of the codeword test pattern indices in perturbed p positions with even and odd number of 1's, respectively.

20. A method for decoding product codes, said method comprising the steps of:
identifying sets of codeword test pattern indices in perturbed p positions with an even and odd number of ones, wherein p equals the number of least reliable bits; and
recursively determining the remaining sets from an initial first odd set,
$${ϕ}_{0}^{odd} = \{ 1 \} ,$$
and even set,
$${ϕ}_{0}^{even} = \{ 0 \} ,$$
wherein the step of recursively determining includes the step of calculating the result from the equations
$${ϕ}_{k}^{even} = \{ {ϕ}_{k - 1 ,}^{even} {ϕ}_{k - 1}^{odd} ⊕ {2}^{k} and {ϕ}_{k}^{odd} = \{ {ϕ}_{k - 1 ,}^{odd} {ϕ}_{k - 1}^{even} ⊕ {2}^{k} \} ,$$
wherein k=1,2, . . . , p−1, and φ ⊕ z denotes the operation where the integer z is added to each element of set φ, wherein
$${ϕ}_{k}^{even} and {ϕ}_{k}^{odd}$$
denote the sets of the codeword test pattern indices in perturbed p positions with even and odd number of 1's, respectively.

21. A method for decoding product codes, said method comprising the steps of:
determining an inner product value representing the vector distance between a received vector codeword and a candidate vector codeword; and
designating the candidate vector codeword that includes the highest inner product value as the decoded codeword.

22. The method of claim 21, wherein the step of determining an inner product includes the step of calculating the result of the equation lᵢ=R·Ĉⁱ=rₑₚ(2ⁱₑₚ−1)+uᵢ, wherein R is the received vector codeword, Ĉ is the candidate vector codeword, rₑₚ is the received even parity codeword, ⁱₑₚ is the jth bit position of the candidate codeword, and
$${u}_{i} = {\sum }_{v = 0}^{n - 1} {r}_{v} ( {2}_{v}^{i} - 1 ) ,$$
wherein v equals an integer value at least equal to zero, wherein rᵥ is the received value vector codeword for the vth bit position, and uᵢ represents an updated metric.

23. The method of claim 21, further including the step of calculating a partial metric for a first candidate codeword from a test pattern.

24. The method of claim 23, further including the step of determining a partial metric for subsequent candidate codewords recursively as a function of the partial metric determined for a candidate codeword previously determined.

25. The method of claim 24, wherein the step of calculating a partial metric for a first candidate codeword includes the step of calculating a result from the equation
$${h}_{0} = {\sum }_{v = 0}^{n - 1} {r}_{v} ( 2 {y}_{v} - 1 ) 1 {y}_{j0} = … = {y}_{jp - 1} = 0 ,$$
wherein h is the partial metric, wherein rᵥ(2yᵥ−1)=−rᵥ, if yᵥ=0, wherein rᵥ(2yᵥ−1)=+rᵥ, if yᵥ=1, wherein y is a hard decision polynomial of the form \overline{y}(x)=y₀+y₁x+y₂x²+ . . . +yₙ₋₁xⁿ⁻¹.

26. The method of claim 21, wherein the step of calculating a partial metric for subsequent candidate codewords includes the step of calculating a result from the equation h₂b₊ₖ=hₖ+2r_{jb,}, wherein k=0, . . . , 2^{b}−1 and b=0, . . . p−1, wherein p equals the number of least reliable bits.

27. The method of claim 21, wherein the determining steps include calculating 5(2^{p})+n−2 mathematical operations, wherein n is an integer number and p equals the number of least reliable bits.

28. The method of claim 21, further including the step of relating the inner product to extrinsic information, wherein the step of relating includes the step of calculating a result from the equation Λ(dⱼ)=[(R·D−R·\hat{D})/2](2dⱼ−1), wherein R is a received vector, D is a decided codeword after decoding, and \hat{D} is a most likely competing codeword among candidate codewords.

29. A method for decoding product codes, said method comprising the steps of:
expressing a Euclidean distance metric into an inner product form;
calculating the inner product with a partial metric; and
relating the inner product to extrinsic information.

30. The method of claim 29, wherein the step of expressing includes the step of expressing the squared Euclidean distance between a received vector R and a candidate codeword
$${\hat{C}}^{i} as {L}_{i} = n + 1 - 2 {l}_{i} + {r}_{ep}^{2} + {\sum }_{v = 0}^{n - 1} {r}_{v}^{2} ,$$
wherein lᵢ=R·Ĉⁱ=rₑₚ(2ⁱₑₚ−1)+uᵢ, wherein R is the received vector codeword, Ĉ is the candidate vector codeword, rₑₚ is the received even parity codeword, ⁱₑₚ is the jth bit position of the candidate codeword, and
$${u}_{i} = {\sum }_{v = 0}^{n - 1} {r}_{v} ( {2}_{v}^{i} - 1 ) ,$$
wherein v equals an integer value at least equal to zero, wherein rᵥ is the received value vector codeword for the vth bit position, and uᵢ represents an updated metric.

31. The method of claim 29, wherein the step of calculating includes the steps of calculating a partial metric for a first candidate codeword from a test pattern and determining a partial metric for subsequent candidate codewords recursively as a function of the partial metric determined for a candidate codeword previously determined.

32. The method of claim 31, wherein the step of calculating a partial metric for a first candidate codeword includes the step of calculating a result from the equation h₀
$${h}_{0} = {\sum }_{v = 0}^{n - 1} {r}_{v} ( 2 {y}_{v} - 1 ) 1 {y}_{j0} = … = {y}_{jp - 1} = 0 ,$$
wherein h is the partial metric, wherein rᵥ(2yᵥ−1)=−rᵥ, if yᵥ=0, wherein rᵥ(2yᵥ−1)=+rᵥ, if yᵥ=1, wherein y is a hard decision polynomial of the form \overline{y}(x)=y₀+y₁x+y₂x²+ . . . +yₙ₋₁xⁿ⁻¹.

33. The method of claim 31, wherein the step of calculating a partial metric for subsequent candidate codewords includes the step of calculating a result from the equation h₂b₊ₖ=hₖ+2r_{jb,}, wherein k=0, . . . , 2^{b}−1 and b=0, . . . p−1, wherein p equals the number of least reliable bits.

34. The method of claim 29, wherein the step of relating includes the step of calculating a result from the equation Λ(dⱼ)=[(R·D−R·\hat{D})/2](2dⱼ−1), wherein R is a received vector, D is the decided codeword after decoding, and \hat{D} is the most likely competing codeword among the candidate codewords.

35. A method for decoding product codes, said method comprising the steps of:
setting a weight parameter for product decoding to a constant; and
setting a reliability parameter for product decoding to a constant.

36. The method of claim 35, wherein the step of setting the weight parameter to a constant includes setting the weight parameter to 0.5.

37. The method of claim 36, wherein the weight parameter is represented by the symbol γ.

38. The method of claim 35, wherein the step of setting the reliability parameter to a constant includes setting the reliability parameter to 1.0.

39. The method of claim 38, wherein the weight parameter is represented by the symbol β.

40. A system for decoding product codes, said system comprising:
logic configured to generate syndromes for a first codeword test pattern, wherein the logic is further configured to generate syndromes for subsequent codeword test patterns using a recursive function of the syndromes generated for a codeword test pattern previously generated.

41. The system of claim 40, wherein the logic is further configured to perform multiplication and addition operations to generate syndromes for the first codeword test pattern.

42. The system of claim 40, wherein the logic is further configured to perform operations included in generating the syndromes for the previous codeword test patterns plus one addition operation to generate the syndromes for the subsequent codeword test patterns.

43. The system of claim 40, wherein the logic is further configured to calculate a result for the equation
$${s}_{0} = {\sum }_{j = 0}^{n - 1} {c}_{j}^{0} {α}^{j} ,$$
wherein cⱼ⁰ is the bit value in a jth position in a test pattern codeword, wherein j is an integer value at least equal to zero, wherein α^{j} is an abstract quantity in a finite field.

44. The system of claim 43, wherein the logic is further configured to calculate a result for the equation S₂b₊ₖ=Sₖ+α^{j}^{^{b}}, wherein b=0, . . . , p−1 and k=0, . . . , 2^{b}−1, wherein p equals the number of least reliable bits, wherein test patterns (TP) TP₂_{^{b}}₊ₖ and TPₖ differ only in bit position j_{b}ⁱ.

45. The system of claim 40, wherein the logic is further configured to calculate n+2^{p}−1 mathematical operations to generate syndromes, wherein n is an integer number and p equals the number of least reliable bits.

46. The system of claim 40, wherein the logic is further configured to indicates an error position in the codeword test pattern for a non-zero value for a syndrome.

47. The system of claim 40, wherein the logic is further configured to order the test patterns in a 2^{p} binary logic table to calculate syndromes, wherein p equals the number of least reliable bits, wherein bit values between rows differ by one bit.

48. The system of claim 40, wherein the logic includes at least one of a discrete logic circuit having logic gates for implementing logic functions upon data signals, an application specific integrated circuit having combinational logic gates, a programmable gate array, and a field programmable gate array.

49. The system of claim 40, wherein the logic includes at least one of software and hardware in a computer readable medium.

50. The system of claim 40, further including at least one of a processor, memory, and a threshold device that communicates with the logic in providing decoding functionality.

51. The system of claim 50, wherein the processor and the logic are located in separate devices.

52. The system of claim 50, wherein the processor and the logic are located in the same device.

53. A system for decoding product codes, said system comprising:
logic configured to generate syndromes for a first codeword test pattern, wherein the processor is further configured with the logic to calculate a result for the equation
$${s}_{0} = {\sum }_{j = 0}^{n - 1} {c}_{j}^{0} {α}^{j} ,$$
wherein cⱼ⁰ is the bit value in a jth position in a test pattern codeword, wherein j is an integer value at least equal to zero, wherein α^{j} is an abstract quantity in a finite field, wherein the logic is further configured to generate syndromes for subsequent codeword test patterns using a recursive function of the syndromes generated for a codeword test pattern previously generated, wherein the logic is further configured to calculate a result for the equation S₂b₊ₖ=Sₖ+α^{j}^{^{b}}, wherein b=0, . . . , p−1 and k=0, . . . , 2^{b}−1, wherein p equals the number of least reliable bits, wherein test patterns (TP) TP₂_{^{b}}₊ₖ and TPₖ differ only in bit position j_{ib}.

54. A system for decoding product codes, said system comprising:
logic configured to determine an even parity function and an odd parity function for a codeword test pattern, wherein the odd parity function is a function of the even parity function, wherein the logic is further configured to determine an even parity codeword test pattern having an even number of ones from the modulo two of the summation of the even parity function and at least one of a zero and a nonzero syndrome for a jth bit position, wherein j is an integer value at least equal to zero, otherwise determine an even parity codeword test pattern having an odd number of ones from the modulo two of the summation of the odd parity function and at least one of a zero and a nonzero syndrome for a jth bit position.

55. The system of claim 54, wherein the logic is further configured to calculate a result for the equation
$${f}_{even} = [ {\sum }_{j \neq j0 , … , lp - 1} {y}_{1} ]$$
mod 2, wherein p equals the number of least reliable bits, wherein y is a hard decision polynomial of the form \overline{y}(x)=y₀+y₁x+y₂x²+ . . . +yₙ₋₁xⁿ⁻¹.

56. The system of claim 55, wherein the logic is further configured to calculate a result for the equation ƒ_{odd}=[ƒₑᵥₑₙ+1] mod 2.

57. The system of claim 54, wherein the logic is further configured to determine the even parity codeword test pattern, Ĉⁱₑₚ, having an even number of ones, by calculating a result for the equation Ĉⁱₑₚ=[ƒₑᵥₑₙ+Ω(Sᵢ)] mod 2, wherein Ω(Sᵢ)=1, if Sᵢ≠0, and wherein Ω(Sᵢ)=0, if Sᵢ=0, wherein Sᵢ wherein Sᵢ is a syndrome calculation for the ith test pattern, wherein i is an integer value at least equal to zero.

58. The system of claim 57, wherein the logic is further configured to determine the even parity codeword test pattern having an odd number of ones by calculating a result for the equation ĉⁱₑₚ=[ƒ_{odd}+Ω(Sᵢ)] mod 2.

59. The system of claim 54, wherein the logic is further configured to identify the sets of codeword test pattern indices in perturbed p positions with an even and odd number of ones, wherein p equals the number of least reliable bits.

60. The system of claim 59, wherein the logic is further configured to recursively determine the remaining sets from an initial first odd set,
$${ϕ}_{0}^{odd} = \{ 1 \} ,$$
and even set,
$${ϕ}_{0}^{even} = \{ 0 \} .$$

61. The system of claim 60, wherein the logic is further configured to calculate the result from the equations
$${ϕ}_{k}^{even} = \{ {ϕ}_{k - 1 ,}^{even} {ϕ}_{k - 1}^{odd} ⊕ {2}^{k} and {ϕ}_{k}^{odd} = \{ {ϕ}_{k - 1 ,}^{odd} {ϕ}_{k - 1}^{even} ⊕ {2}^{k} \} ,$$
wherein k=1,2, . . . , p−1, and φ ⊕ z denotes the operation where the integer z is added to each element of set φ, wherein
$${ϕ}_{k}^{even} and {ϕ}_{k}^{odd}$$
denote the sets of the codeword test pattern indices in perturbed p positions with even and odd number of 1's, respectively.

62. The system of claim 54, wherein the logic is further configured to calculate n−p+1+2^{p} mathematical operations, wherein n is an integer number and p equals the number of least reliable bits.

63. The system of claim 54, wherein the logic includes at least one of a discrete logic circuit having logic gates for implementing logic functions upon data signals, an application specific integrated circuit having combinational logic gates, a programmable gate array, and a field programmable gate array.

64. The system of claim 54, wherein the logic includes at least one of software and hardware in a computer readable medium.

65. The system of claim 54, further including at least one of a processor, memory, and a threshold device that communicates with the logic in providing decoding functionality.

66. The system of claim 65, wherein the processor and the logic are located in separate devices.

67. The system of claim 65, wherein the processor and the logic are located in the same device.

68. A system for decoding product codes, said system comprising:
logic configured to determine an even parity function and an odd parity function for a codeword test pattern, wherein the odd parity function is a function of the even parity function, wherein the logic is further configured to calculate a result for the equation
$${f}_{even} = [ {\sum }_{j \neq jo , . , {j}_{p - 1}}^{} {y}_{1} ]$$
mod 2, wherein p equals the number of least reliable bits, wherein y is a hard decision polynomial of the form \overline{y}(x)=y₀+y₁x+y₂x²+ . . . +yₙ₋₁xⁿ⁻¹, wherein the logic is further configured to calculate a result for the equation ƒ_{odd}=[ƒₑᵥₑₙ+1] mod 2, wherein the logic is further configured to determine the even parity codeword test pattern, Ĉⁱₑₚ, having an even number of ones, from the modulo two of the summation of the even parity function and at least one of a zero and a nonzero syndrome for a jth bit position, wherein the logic is further configured to determine the even parity codeword test pattern, Ĉⁱₑₚ, having an even number of ones, by calculating a result for the equation Ĉⁱₑₚ=[ƒₑᵥₑₙ+Ω(Sᵢ)] mod 2, wherein Ω(Sᵢ)=1, if Sᵢ≠0, and wherein Ω(Sᵢ)=0, if Sᵢ=0, wherein Sᵢ wherein Sᵢ is a syndrome calculation for the ith test pattern, wherein i is an integer value at least equal to zero, otherwise the logic is further configured to determine the even parity codeword test pattern, having an odd number of ones, from the modulo two of the summation of the odd parity function and at least one of a zero and a nonzero syndrome for a jth bit position, wherein the logic is further configured to determine the even parity codeword test pattern, having an odd number of ones, by calculating a result for the equation ĉⁱₑₚ=[ƒ_{odd}+Ω(Sᵢ)] mod 2, wherein the logic is further configured to identify the sets of codeword test pattern indices in perturbed p positions with an even and odd number of ones, wherein the logic is further configured to recursively determine the remaining sets from an initial first odd set
$${ϕ}_{0}^{odd} = \{ 1 \} ,$$
and even set,
$${ϕ}_{0}^{even} = \{ 0 \} ,$$
wherein the logic is further configured to calculate the result from the equations
$${ϕ}_{k}^{even} = \{ {ϕ}_{k - 1}^{even} {ϕ}_{k - 1}^{odd} ⊕ {2}^{k} and {ϕ}_{k}^{odd} = \{ {ϕ}_{k - 1}^{odd} , {ϕ}_{k - 1}^{even} ⊕ {2}^{k} \} ,$$
wherein k=1,2, . . . , p−1, and φ ⊕ z denotes the operation where the integer z is added to each element of set φ, wherein
$${ϕ}_{k}^{even} and {ϕ}_{k}^{odd}$$
denote the sets of the codeword test pattern indices in perturbed p positions with even and odd number of 1's, respectively.

69. A system for decoding product codes, said system comprising:
logic configured to identify sets of codeword test pattern indices in perturbed p positions with an even and odd number of ones, wherein p equals the number of least reliable bits, wherein the logic is further configured to recursively determine the remaining sets from an initial first odd set,
$${ϕ}_{0}^{odd} = \{ 1 \} ,$$
and even set,
$${ϕ}_{0}^{even} = \{ 0 \} ,$$
wherein the logic is further configured to calculate the result from the equations
$${ϕ}_{k}^{even} = \{ {ϕ}_{k - 1}^{even} {ϕ}_{k - 1}^{odd} ⊕ {2}^{k} and {ϕ}_{k}^{odd} = \{ {ϕ}_{k - 1}^{odd} , {ϕ}_{k - 1}^{even} ⊕ {2}^{k} \} ,$$
wherein k=1,2, . . . , p−1, and φ ⊕ z denotes the operation where the integer z is added to each element of set φ, wherein
$${ϕ}_{k}^{even} and {ϕ}_{k}^{odd}$$
denote the sets of the codeword test pattern indices in perturbed p positions with even and odd number of 1's, respectively.

70. A system for decoding product codes, said system comprising:
logic configured to determine an inner product value representing the vector distance between a received vector codeword and a candidate vector codeword, wherein the logic is further configured to designate the candidate vector codeword that includes the highest inner product value as the decoded codeword.

71. The system of claim 70, wherein the logic is further configured to calculate the result of the equation lᵢ=R·Ĉⁱ=rₑₚ(2ⁱₑₚ−1)+uᵢ, wherein R is the received vector codeword, Ĉ is the candidate vector codeword, rₑₚ is the received even parity codeword, ⁱₑₚ is the jth bit position of the candidate codeword, and
$${u}_{i} = {\sum }_{v = 0}^{n - 1} {r}_{v} ( {2}_{v}^{i} - 1 ) ,$$
wherein v equals an integer value at least equal to zero, wherein rᵥ is the received value vector codeword for the vth bit position, and uᵢ represents an updated metric.

72. The system of claim 70, wherein the logic is further configured to calculate a partial metric for a first candidate codeword from a test pattern.

73. The system of claim 72, wherein the logic is further configured to determine a partial metric for subsequent candidate codewords recursively as a function of the partial metric determined for a candidate codeword previously determined.

74. The system of claim 73, wherein the logic is further configured to calculate a partial metric for a first candidate codeword by calculating a result from the equation h₀=
$${\sum }_{v = 0}^{n - 1} {r}_{v} ( 2 {y}_{v} - 1 ) {ly}_{j0} = … = {y}_{jp - 1} = 0 ,$$
wherein h is the partial metric, wherein rᵥ(2yᵥ−1)=−rᵥ, if yᵥ=0, wherein rᵥ(2yᵥ−1)=+rᵥ, if yᵥ=1, wherein y is a hard decision polynomial of the form \overline{y}(x)=y₀+y₁x+y₂x²+ . . . +yₙ₋₁xⁿ⁻¹.

75. The system of claim 70, wherein the logic is further configured to calculate a partial metric for subsequent candidate codewords by calculating a result from the equation h₂b₊ₖ=hₖ+2r_{jb}, wherein k=0, . . . , 2^{b}−1 and b=0, . . . p−1, wherein p equals the number of least reliable bits.

76. The system of claim 70, wherein the logic is further configured to calculate 5(2^{p})+n−2 mathematical operations, wherein n is an integer number and p equals the number of least reliable bits.

77. The system of claim 70, wherein the logic is further configured to relate the inner product to extrinsic information, wherein the logic is further configured to calculate a result from the equation Λ(dⱼ)=[(R·D−R·\hat{D})/2](2dⱼ−1), wherein R is a received vector, D is a decided codeword after decoding, and \hat{D} is a most likely competing codeword among candidate codewords.

78. The system of claim 70, wherein the logic includes at least one of a discrete logic circuit having logic gates for implementing logic functions upon data signals, an application specific integrated circuit having combinational logic gates, a programmable gate array, and a field programmable gate array.

79. The system of claim 70, wherein the logic includes at least one of software and hardware in a computer readable medium.

80. The system of claim 70, further including at least one of a processor, memory, and a threshold device that communicates with the logic in providing decoding functionality.

81. The system of claim 80, wherein the processor and the logic are located in separate devices.

82. The system of claim 80, wherein the processor and the logic are located in the same device.

83. A system for decoding product codes, said system comprising:
logic configured to express a Euclidean distance metric into an inner product form, wherein the logic is further configured to calculate the inner product with a partial metric, wherein the logic is further configured to relate the inner product to extrinsic information.

84. The system of claim 83, wherein the logic is further configured to express the squared Euclidean distance between a received vector R and a candidate codeword Ĉⁱ as
$${L}_{i} = n + 1 - 2 {l}_{i} + {r}_{ep}^{2} + {\sum }_{v = 0}^{n - 1} {r}_{v}^{2} ,$$
wherein lᵢ=R·Ĉⁱ=rₑₚ(2ⁱₑₚ−1)+uᵢ, wherein R is the received vector codeword, Ĉ is the candidate vector codeword, rₑₚ is the received even parity codeword, ⁱₑₚ is the jth bit position of the candidate codeword, and uᵢ
$${u}_{i} = {\sum }_{v = 0}^{n - 1} {r}_{v} ( {2}_{v}^{i} - 1 ) ,$$
wherein v equals an integer value at least equal to zero, wherein rᵥ is the received value vector codeword for the vth bit position, and uᵢ represents an updated metric.

85. The system of claim 83, wherein the logic is further configured to calculate a partial metric for a first candidate codeword from a test pattern and determine a partial metric for subsequent candidate codewords recursively as a function of the partial metric determined for previous candidate codewords.

86. The system of claim 85, wherein the logic is further configured to calculate a partial metric for a first candidate codeword by calculating a result from the equation h₀=
$${\sum }_{v = 0}^{n - 1} {r}_{v} ( 2 {y}_{v} - 1 ) {ly}_{j0} = … = {y}_{jp - 1} = 0 ,$$
wherein h is the partial metric, wherein rᵥ(2yᵥ−1)=−rᵥ, if yᵥ=0, wherein rᵥ(2yᵥ−1)=+rᵥ, if yᵥ=1, wherein y is a hard decision polynomial of the form \overline{y}(x)=y₀+y₁x+y₂x²+ . . . +yₙ₋₁xⁿ⁻¹.

87. The system of claim 85, wherein the logic is further configured to calculate a partial metric for the subsequent candidate codewords by calculating a result from the equation h₂b₊ₖ=hₖ+2r_{jb}, wherein k=0, . . . , 2^{b}−1 and b=0, . . . p−1, wherein p equals the number of least reliable bits.

88. The system of claim 83, wherein the logic is further configured to relate by calculating a result from the equation Λ(dⱼ)=[(R·D−R·\hat{D})/2](2dⱼ−1), wherein R is a received vector, D is the decided codeword after decoding, and D is the most likely competing codeword among the candidate codewords.

89. The system of claim 83, wherein the logic includes at least one of a discrete logic circuit having logic gates for implementing logic functions upon data signals, an application specific integrated circuit having combinational logic gates, a programmable gate array, and a field programmable gate array.

90. The system of claim 83, wherein the logic includes at least one of software and hardware in a computer readable medium.

91. The system of claim 83, further including at least one of a processor, memory, and a threshold device that communicates with the logic in providing decoding functionality.

92. The system of claim 91, wherein the processor and the logic are located in separate devices.

93. The system of claim 91, wherein the processor and the logic are located in the same device.

94. A system for decoding product codes, said system comprising:
logic configured to set a weight parameter for product decoding to a constant, wherein the logic is further configured to set a reliability parameter for product decoding to a constant.

95. The system of claim 94, wherein the logic is further configured to set the weight parameter to 0.5.

96. The system of claim 95, wherein the weight parameter is represented by the symbol γ.

97. The system of claim 94, wherein the logic is further configured to set the reliability parameter to 1.0.

98. The system of claim 97, wherein the weight parameter is represented by the symbol β.

99. The system of claim 94, wherein the logic includes at least one of a discrete logic circuit having logic gates for implementing logic functions upon data signals, an application specific integrated circuit having combinational logic gates, a programmable gate array, and a field programmable gate array.

100. The system of claim 94, wherein the logic includes at least one of software and hardware in a computer readable medium.

101. The system of claim 94, further including at least one of a processor, memory, and a threshold device that communicates with the logic in providing decoding functionality.

102. The system of claim 101, wherein the processor and the logic are located in separate devices.

103. The system of claim 101, wherein the processor and the logic are located in the same device.
